(19) United States
(12) Patent Application Publication
(10) Pub. No.: US 2026/0149219 A1
(43) Pub. Date: May 28, 2026

(54) MID-RETENTION CABLE ORGANIZERS AND OVERMOLDS

(71) Applicant: Molex, LLC, Lisle, IL (US)

(72) Inventors: Gianni Ryan Bardella, Maumelle, AR (US); Arturo Casares Valdes, Conway, AR (US)

(21) Appl. No.: 19/372,951

(22) Filed: Oct. 29, 2025

Related U.S. Application Data
(60) Provisional application No. 63/726,245, filed on Nov. 28, 2024.

(51) Int. Cl. H01R 13/518; H01R 12/72; H01R 13/514

(52) U.S. Cl. CPC H01R 13/518; H01R 13/514; H01R 12/722

(57) ABSTRACT

Cable organizers and overmolds for stress and strain relief in termination assemblies of pluggable modules and related cable assemblies are described. An example termination assembly includes a printed circuit board (PCB), a board-edge cable organizer secured along an edge of the PCB, and a cable extending to and being electrically coupled with the PCB. The board-edge cable organizer includes one or more cable channels. The cable extends in and along a cable channel of the board-edge cable organizer before being terminated to the PCB. The board-edge cable organizer can be secured over the edge of the PCB in a cantilevered arrangement in some examples. The board-edge cable organizer can also include cable channels on first and second sides of the board-edge cable organizer, and first and second cables can extend along cable channels on the first and second sides of the board-edge cable organizer before being terminated to the PCB.

### BACKGROUND

The amount of data processed by computers, computing systems, and computing environments continues to increase. For example, data centers can include hundreds of computing and networking systems interconnected using optical cables, copper cables, and various connectors, cable assemblies, and terminations between them. The data throughput of these interconnects is high and increasing. As examples, many data centers incorporate a combination of 10 Gigabit Ethernet (10 GbE), 25 GbE, 50 GbE, and 100 GbE network interfaces and interconnects. 200 GbE, 400 GbE, and 800 GbE interconnection technology is also being developed and deployed. Other interconnection solutions rely upon 56 Gigabit per second (Gb/s), 112 Gb/s, and 224 Gb/s interconnection technologies, and interconnection technologies are being developed to support higher data rates. A range of cable assemblies are available for the data interconnects. A variety of designs exist for each cable assembly, depending on the requirements of the data communications environment in which the connectors are used.

The small form-factor pluggable (SFP) module format is a compact, hot-pluggable network interface module format used for data interconnects, and SFP modules are commonly used for interconnects in data centers. An SFP interface on a computing or networking system is a modular slot for a media-specific transceiver, such as a fiber-optic or a copper cable assembly. Cable assemblies can include SFP pluggable transceiver modules at one or both ends of a copper, fiber-optic, or other type of interconnecting cable. SFP pluggable transceiver modules can be inserted into SFP interfaces for data interconnections.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

Aspects of cable organizers and overmolds for stress and strain relief in termination assemblies of pluggable modules, including SFP pluggable modules and related assemblies, are described. The termination assemblies, cable organizers, overmolds, and other features described herein can be relied upon in SFP and related pluggable modules, but the concepts can also be extended to use in other types of modules and termination assemblies. An example termination assembly includes a printed circuit board (PCB), a board-edge cable organizer secured along an edge of the PCB, and a cable extending to and being electrically coupled with the PCB. The board-edge cable organizer includes one or more cable channels. The cable extends in and along a cable channel of the board-edge cable organizer before being terminated to the PCB. The board-edge cable organizer can be secured over the edge of the PCB in a cantilevered arrangement in some examples. Another example termination assembly includes a PCB, a board-edge cable organizer secured along an edge of the PCB, and a cable extending along the board-edge cable organizer and being electrically coupled with the PCB.

In other aspects, the termination assembly can also include an inline cable organizer. In this case, from one end, the cable can extend through the inline cable organizer, in and along the cable channel of the board-edge cable organizer, and to the PCB. The termination assembly can also include a cable bundle overmold. In that case, from one end, the cable can extend through the inline cable organizer, through the cable bundle overmold, in and along the cable channel of the board-edge cable organizer, and to the PCB.

In other examples, the termination assembly can include a plurality of cables and a plurality of inline cable organizers, with a first cable extending through a first inline cable organizer and a second cable extending through a second inline cable organizer. The first inline cable organizer can be separated by a first distance from the board-edge cable organizer, and the second inline cable organizer can be separated by a second distance from the board-edge cable organizer different than the first distance.

In other aspects, the board-edge cable organizer can also include a board-side mounting surface, a plurality of mounting stakes, and a plurality of cable channels. The board-edge cable organizer can also include a board-edge abutment surface in some cases. The board-side mounting surface can face a top surface of the PCB and the board-edge abutment surface can face a back edge of the PCB, when the board-edge cable organizer is installed with the PCB. Further, the mounting stakes can extend through mounting apertures in the PCB from the top surface to a bottom surface of the PCB. Each of the mounting stakes can include a fastening head over the bottom surface of the PCB.

In some cases, the board-edge cable organizer can also include a number of cable channels and a cable separation pillar between two of the cable channels. The cable separation pillar can include a cable bumper extending beyond an end surface of the cable separation pillar in some cases. The board-edge cable organizer can also include a first plurality of cable channels on a first side of the board-edge cable organizer, and a second plurality of cable channels on a second side of the board-edge cable organizer. A first cable can extend in and along a first cable channel on the first side of the board-edge cable organizer, and a second cable can extend in and along a second cable channel on the second side of the board-edge cable organizer.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 illustrates a perspective view of one end of a cable assembly according to aspects of the present disclosure.

FIG. 2A illustrates a perspective view of a printed circuit board (PCB) and termination assembly for a cable bundle of the cable assembly shown in FIG. 1 according to aspects of the present disclosure.

FIG. 2B illustrates a side view of the PCB and termination assembly shown in FIG. 2A according to aspects of the present disclosure.

FIG. 2C illustrates a detail perspective view of the PCB and termination assembly shown in FIG. 2A according to aspects of the present disclosure.

FIG. 2D illustrates a perspective view of the distal end of a cable in the termination assembly shown in FIG. 2A according to aspects of the present disclosure.

FIG. 2E illustrates another perspective view of the PCB and termination assembly shown in FIG. 2A according to aspects of the present disclosure.

FIG. 2F illustrates another perspective view of the PCB and termination assembly shown in FIG. 2A, with parts omitted, according to aspects of the present disclosure.

FIG. 2G illustrates a perspective view of another example PCB and termination assembly, with parts omitted, according to aspects of the present disclosure.

FIG. 3A illustrates a top perspective view of the PCB and board-edge cable organizer shown in FIG. 2A according to aspects of the present disclosure.

FIG. 3B illustrates a bottom perspective view of the PCB and board-edge cable organizer shown in FIG. 2A according to aspects of the present disclosure.

FIG. 3C illustrates a top perspective view of the PCB and board-edge cable organizer shown in FIG. 2A, separated from each other, according to aspects of the present disclosure.

FIG. 3D illustrates a top perspective view of the PCB and board-edge cable organizer shown in FIG. 2G according to aspects of the present disclosure.

FIG. 3E illustrates a bottom perspective view of the PCB and board-edge cable organizer shown in FIG. 2G according to aspects of the present disclosure.

FIG. 3F illustrates a top perspective view of the PCB and board-edge cable organizer shown in FIG. 2G, separated from each other, according to aspects of the present disclosure.

FIG. 4A illustrates a perspective view of the board-edge cable organizer shown in FIG. 2A according to aspects of the present disclosure.

FIG. 4B illustrates a front view of the board-edge cable organizer shown in FIG. 2A according to aspects of the present disclosure.

FIG. 4C illustrates a side view of the board-edge cable organizer shown in FIG. 2A according to aspects of the present disclosure.

FIG. 5A illustrates the sectional view of the PCB and termination assembly designated A-A in FIG. 2F according to aspects of the present disclosure.

FIG. 5B illustrates the sectional view of the PCB and termination assembly designated B-B in FIG. 2F according to aspects of the present disclosure.

### DETAILED DESCRIPTION

The amount of data processed by computers, computing systems, and computing environments continues to increase. For example, data centers can include hundreds of computing and networking systems interconnected using optical cables, copper cables, and various connectors, cable assemblies, and terminations between them. The small form-factor pluggable (SFP) module format may be a compact, hot-pluggable network interface module format used for data interconnects. SFP pluggable transceiver modules can be inserted into SFP interfaces for data interconnections. An SFP interface on a computing or networking system may be a modular slot for a media-specific transceiver, such as a copper cable or fiber-optic transceiver. Cable assemblies can include SFP pluggable transceiver modules at one or both ends of a copper, fiber-optic, or other type of interconnecting cable or cable bundle.

A range of SFP pluggable transceiver modules are currently available, including small form-factor pluggable double density (SFP-DD), compact small form-factor pluggable (cSFP), SFP+, quad small form-factor pluggable (QSFP), quad small form-factor pluggable double density (QSFP-DD), octal small form factor pluggable (OSFP), and others. SFP pluggable transceiver modules often include one or more printed circuit boards (PCBs) with one or more semiconductor circuit devices or chips and other circuitry mounted to the PCB or PCB. An active electrical cable (AEC) assembly can include one or more SFP pluggable transceiver modules at the free ends of cables or a cable bundle. An AEC assembly can include a PCB and semiconductor chips for signal re-timing, noise reduction, signal integrity improvement, and other functions. Other types of cable assemblies, including passive cable assemblies, can also include PCBs within housings of pluggable modules.

In the context outlined above, aspects of cable organizers and overmolds for stress and strain relief in termination assemblies of pluggable modules, including SFP pluggable modules and related assemblies, are described. The concepts of cable organizers, overmolds, and related features for stress and strain relief are not limited to use with any particular type of cable assembly, and the concepts can be applied and extended to a range of active, passive, and related cable and terminal assemblies. The termination assemblies, cable organizers, overmolds, and other features described herein can be relied upon in SFP and related pluggable modules, but the concepts can also be extended to use in other types of modules and termination assemblies. An example termination assembly includes a printed circuit board (PCB), a board-edge cable organizer secured along an edge of the PCB, and a cable extending to and being electrically coupled with the PCB. The board-edge cable organizer includes one or more cable channels. The cable extends in and along a cable channel of the board-edge cable organizer before being terminated to the PCB. The board-edge cable organizer can be secured over the edge of the PCB in a cantilevered arrangement in some examples. The board-edge cable organizer can also include cable channels on first and second sides of the board-edge cable organizer, and first and second cables can extend along cable channels on the first and second sides of the board-edge cable organizer before being terminated to the PCB.

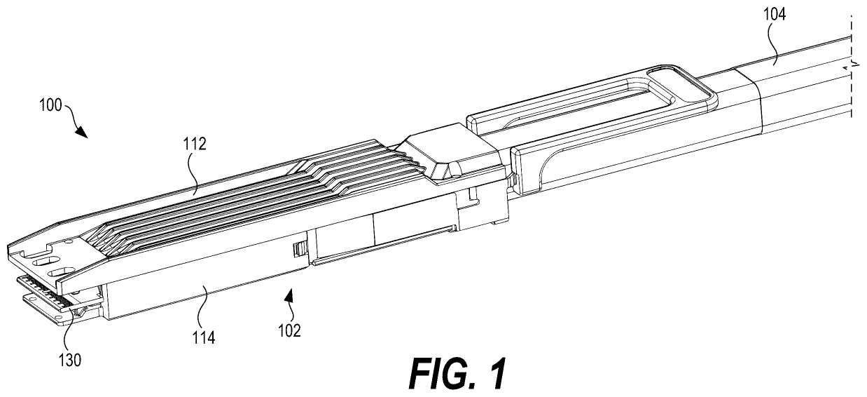

Turning to the drawings, FIG. 1 illustrates a perspective view of a cable assembly 100 according to aspects of the present disclosure. The cable assembly 100 is representative, not drawn to any particular size or scale, and is illustrated to provide example context for modules and termination assemblies that incorporate cable organizers and overmolds for stress and strain relief between cables and PCBs. The cable assembly 100 is not intended to be limited to any particular style or type of cable or cable assembly. The concepts of using cable organizers and overmolds between cables and PCBs, as described herein, are also not limited to use with SFP modules. The concepts can be relied upon in a range of different assemblies including PCBs and cables to maintain the mechanical robustness of the interface between the PCBs and cables, among other benefits.

The cable assembly 100 includes a pluggable transceiver module 102 (also “module 102”) at one end of a cable bundle 104. The cable assembly 100 is an example of an AEC or related type of cable assembly. The module 102, which is described in further detail below, is also representative, and the concepts described herein can be applied to a range of pluggable modules, including SFP, OSFP, SFP-DD, cSFP, SFP+, QSFP, QSFP-DD, and other types of pluggable modules.

The module 102 includes a module shell or housing that encloses a number of components, such as at least one PCB 130, one or more semiconductor chips and other circuitry mounted on the PCB 130, and other components. The module shell includes an upper shell 112, a lower shell 114, and other components. The upper shell 112 and lower shell 114 of the module 102 can be embodied as or formed from a metal or metal alloy, although other types of materials can also be relied upon. In one example, the upper shell 112 and lower shell 114 can be embodied as a die-cast zinc, zinc alloy, or other metals or metal alloys and can be plated in some cases.

The cable bundle 104 can include a number of cables with signal, ground, and/or drain conductors. In one example, the cable bundle 104 includes a number of twinaxial cables, also called twinax cables. Each twinax cable can include a pair of conductors, each surrounded by a dielectric insulator or insulating material, a shield, one or more drain conductors, a jacket, and other features or components. Twinax cables can be particularly suited for use in short-range, high-speed differential data signaling applications. The cable bundle 104 can be embodied by cables other than twinax cables in some cases, including twisted pair cables, shielded twisted pair cables, single-conductor cables, shielded single-conductor cables, single-conductor coaxial cables, and other types of cables. The concepts described herein are not limited to use with any particular type or style of cable, and the concepts can also be applied to fiber-optic and other types of cables.

Cables having larger conductors (e.g., conductors of lower American Wire Gauge (AWG)) may be preferred or needed in some cases to facilitate higher data throughputs. However, larger conductors are capable of transferring and exerting larger forces, including at the locations where the conductors are terminated to PCBs and other termination points. Thus, the use of cables having larger conductors can also contribute to an increased likelihood that the conductors of the cables may break away from the PCB to which the conductors are terminated, particularly where forces are exerted between and among the cables and the PCB. The cable organizers and overmolds described herein can be helpful for stress and strain relief in termination assemblies using larger conductors, as one example, and offer other strain and stress relief benefits.

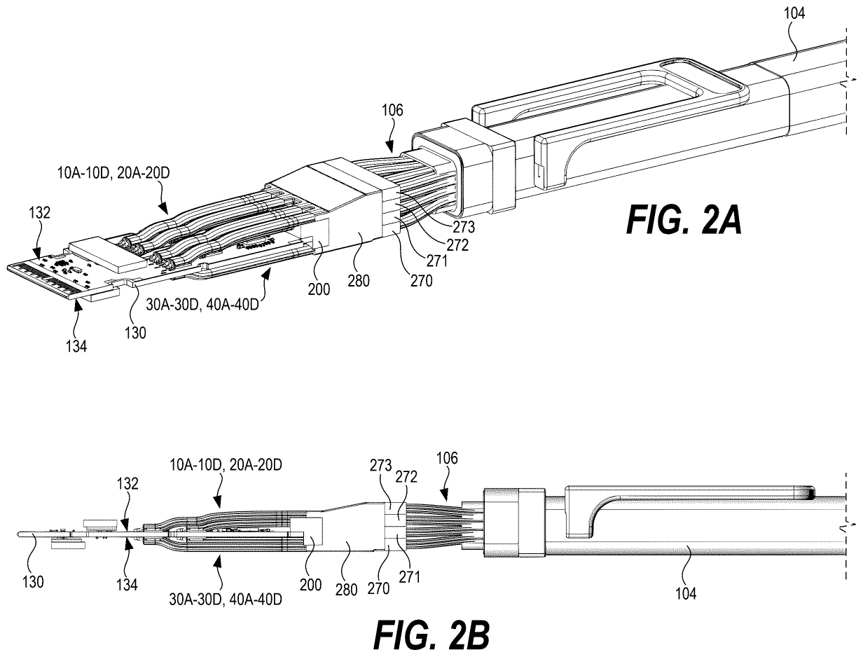

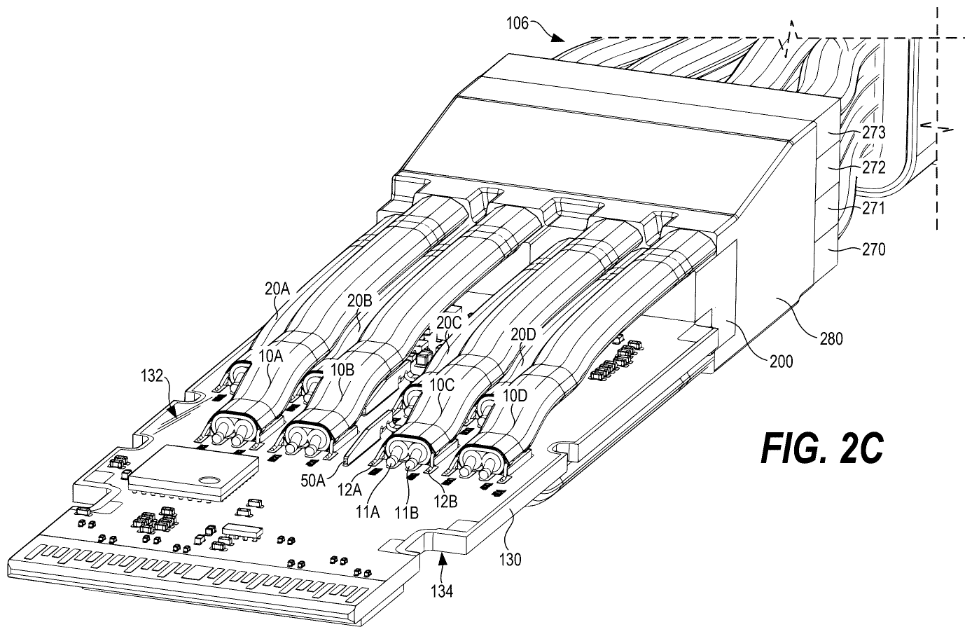

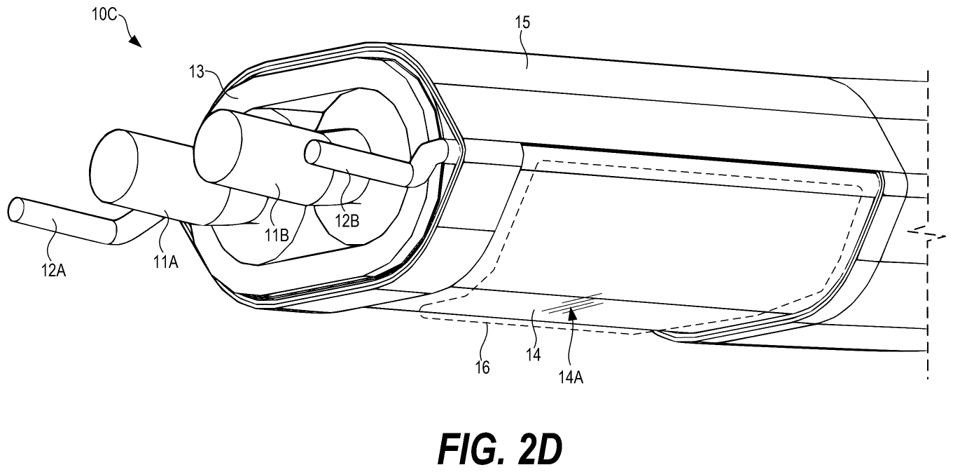

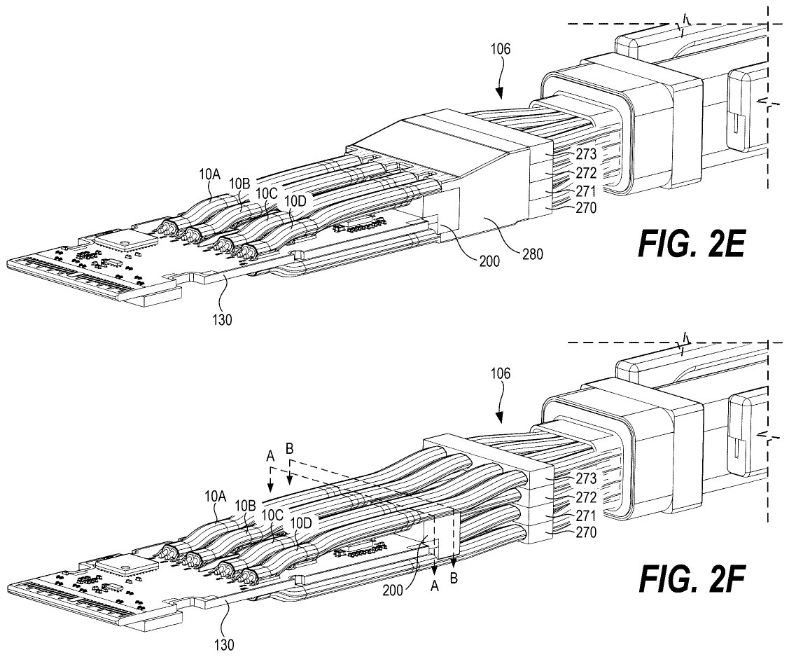

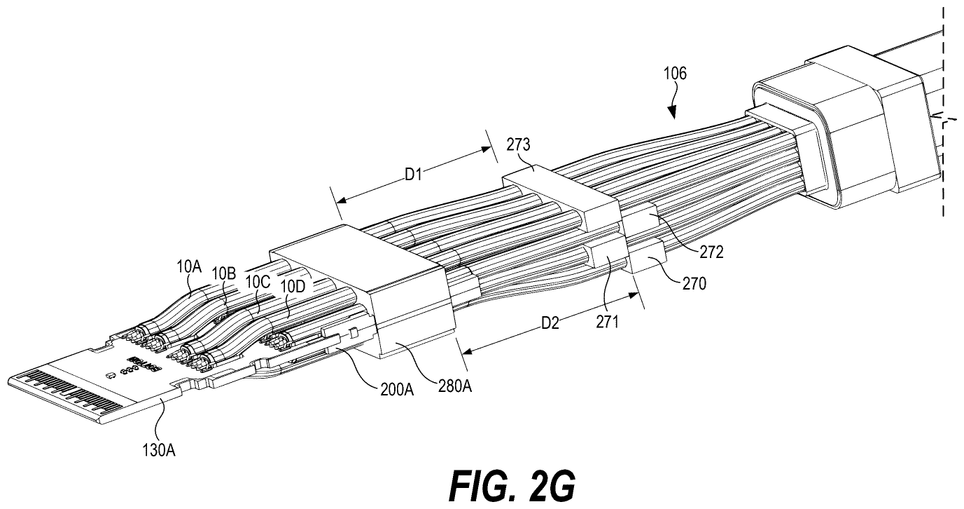

FIG. 2A illustrates a perspective view of the PCB 130 and the cable bundle 104 of the cable assembly 100 shown in FIG. 1, and FIG. 2B illustrates a side view of the PCB 130 and the cable bundle 104. The cable bundle 104 includes a plurality of shielded cables 106 (also “cables 106”), and the cables 106 extend and can terminate to the PCB 130. Thus, as shown in FIGS. 2A and 2B, each of the cables 106 extends and can electrically couple to the PCB 130, and FIGS. 2A and 2B illustrate an example termination assembly of the cable assembly 100 shown in FIG. 1. FIGS. 2A and 2B depict a representative example of a termination assembly including cable organizers and overmolds for stress and strain relief between the cables 106 and the PCB 130. The concepts described herein can be extended to use with other types of termination assemblies, cables, and PCBs.

Referring between FIGS. 2A and 2B, the PCB 130 includes a top surface 132 and a bottom surface 134. The PCB 130 can be embodied as a printed circuit board including a laminated stack of metal layers and dielectric insulating material. One or more semiconductor chips and other circuit components can be electrically coupled to and mounted on the PCB 130 and electrically interconnected among each other by metal traces of the PCB 130. The PCB 130 includes a PCB-style tip interface at the end of the module 102 (see FIG. 1).

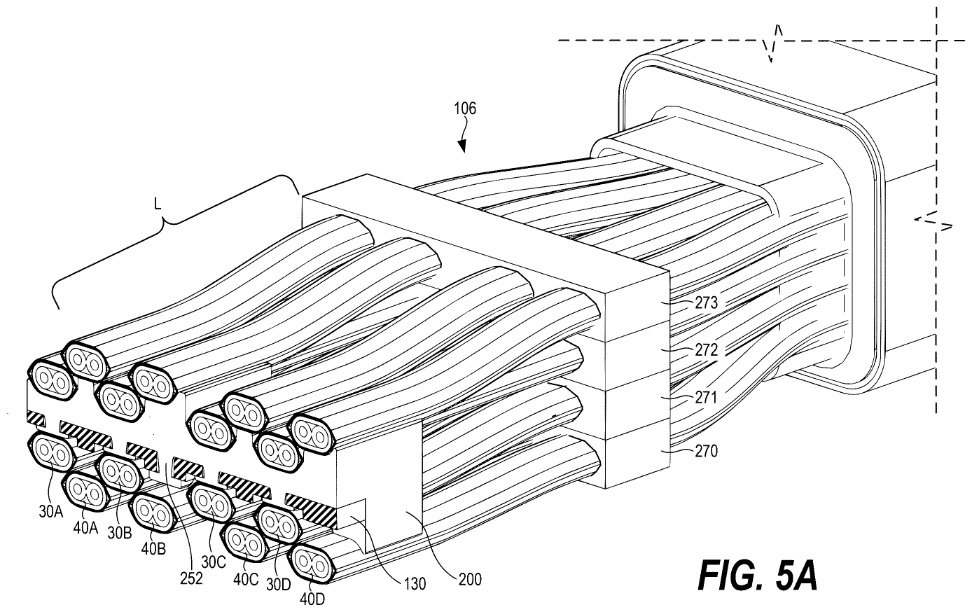

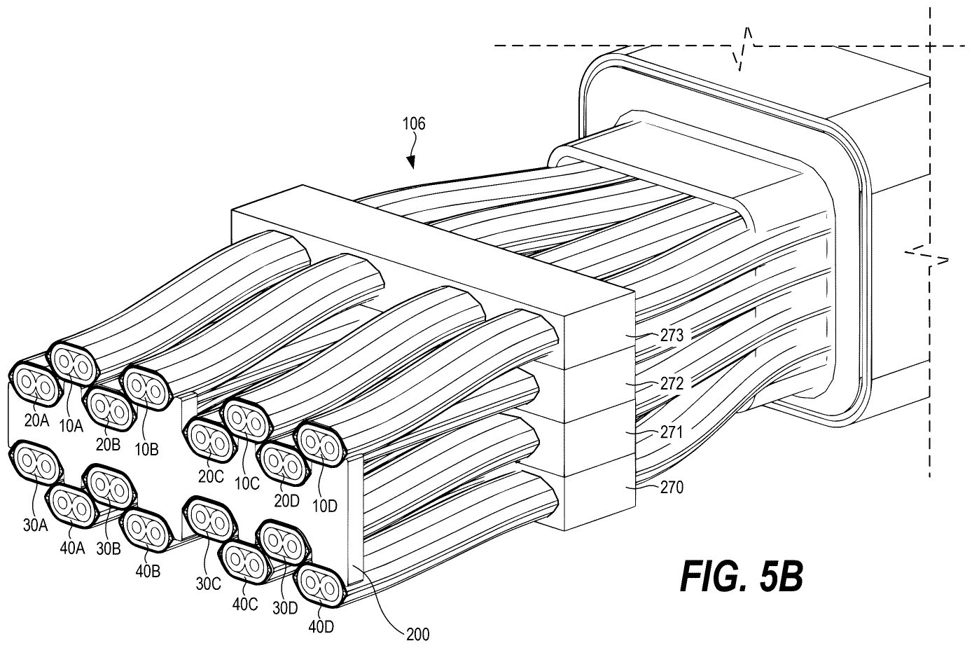

The cable bundle 104 includes a plurality of shielded cables 106, including the cables 10A-10D, 20A-20D, 30A-30D, and 40A-40D (see also FIG. 5B) in the example shown. Each of the cables 106 may be a twinax cable as in the example depicted. The cables have conductors that are electrically coupled and terminated to the PCB 130. As described in further detail below, signal conductors of the cables 106 can be electrically coupled and terminated to signal or trace contact pads on the PCB 130. Ground or drain conductors of the cables 106 can also be electrically coupled and terminated to ground contact pads or surface regions of the PCB 130. More particularly, the signal and ground conductors of the cables 10A-10D and 20A-20D extend and can be electrically coupled to contact pads on the top surface 132 of the PCB 130. The signal and ground conductors of the cables 30A-30D and 40A-40D extend and can be electrically coupled to contact pads on the bottom surface 134 of the PCB 130.

A subset of the cables 106 can be relied upon for data reception (e.g., data RX) and another subset of the cables 106 can be relied upon for data transmission (e.g., data TX) in some cases. The pitch between the longitudinal axis of adjacent cables in a row can be the same in some cases, regardless of whether the cables are relied upon for data RX or TX. In other cases, the pitch between the longitudinal axis of adjacent cables can vary. The pitch between the longitudinal axis of adjacent cables can vary in the same row, can vary among two or more different rows, or can vary among the same and among different rows. The pitch can vary depending on whether or not the cables are relied upon for data RX or TX, as one example, among other reasons.

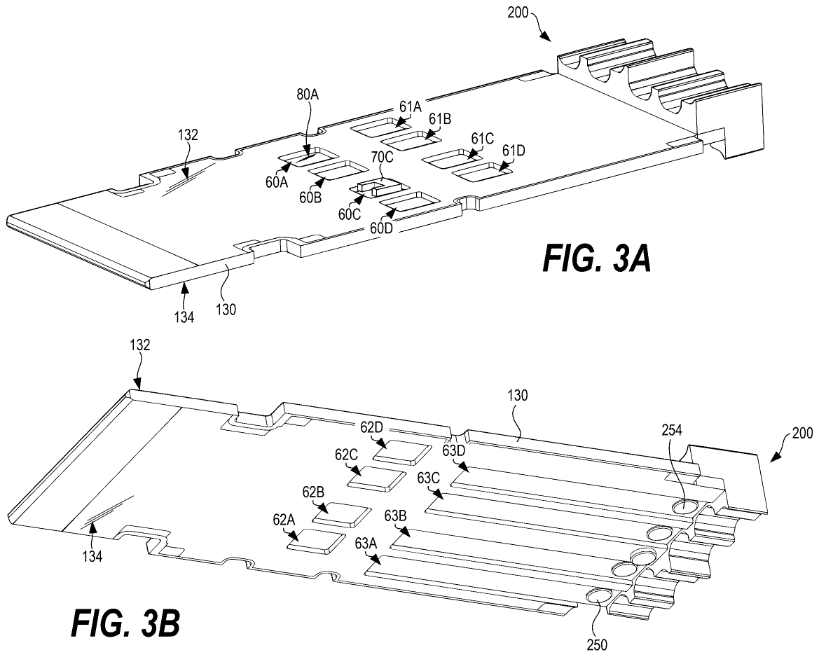

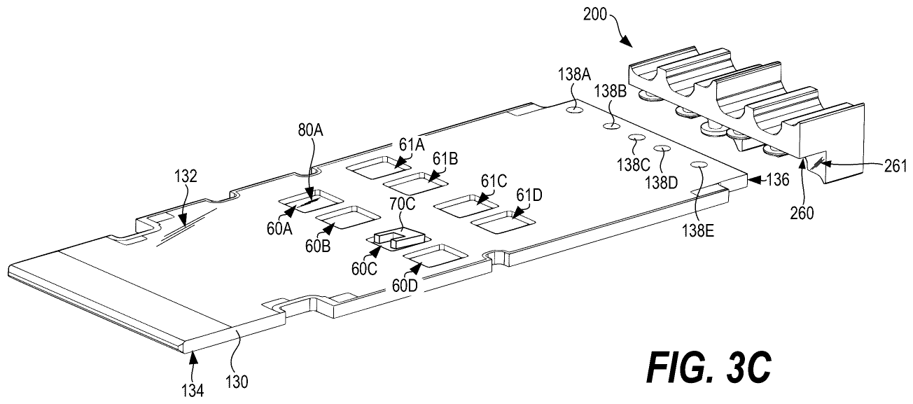

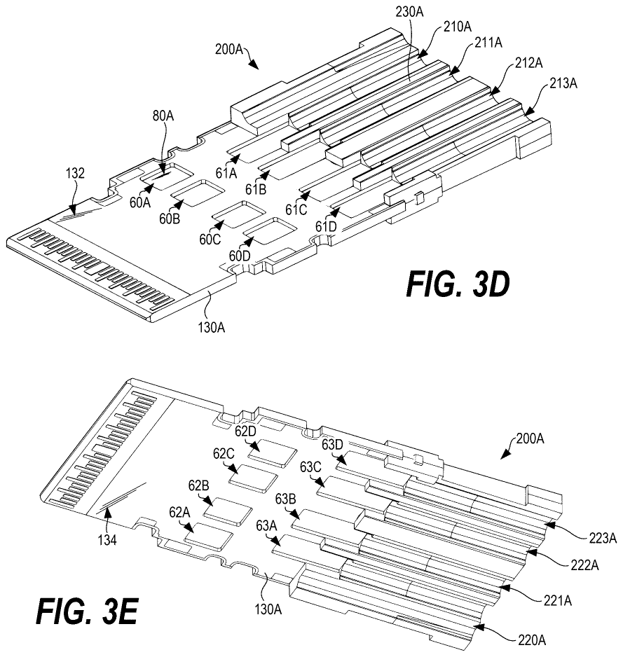

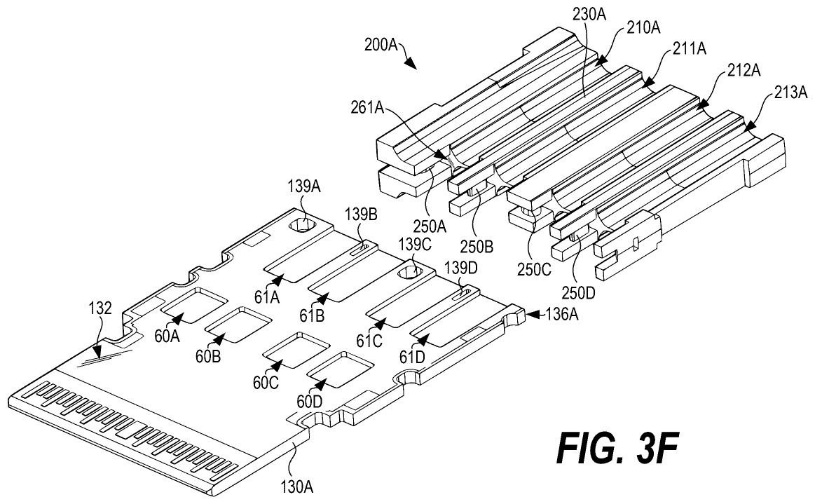

The cables 106 can be organized and supported by a board-edge cable organizer 200 (also “cable organizer 200”), inline cable organizers 270-273 (also “cable organizer 270-273”), and a cable bundle overmold 280. The number of the inline cable organizers 270-273 can vary depending on design needs, and the inline cable organizers 270-273 can vary in shape, size, and position as compared to that shown. The cable organizers 200 and 270-273 and the cable bundle overmold 280 provide stress and strain relief and support the mechanical and electrical connections between the cables 106 and the PCB 130 in the termination assembly shown in FIGS. 2A and 2B. The board-edge cable organizer 200 is secured along an edge of the PCB 130. In the example illustrated, the board-edge cable organizer 200 is secured along and extends over an edge of the PCB 130 in a cantilevered arrangement, as best depicted in FIGS. 3A and 3B. From the cable bundle 104, the cables 106 extend through the inline cable organizers 270-273, through the cable bundle overmold 280, and along cable channels in the board-edge cable organizer 200. From the cable channels in the board-edge cable organizer 200, the cables extend and can be terminated to (e.g., electrically coupled to) the PCB 130.

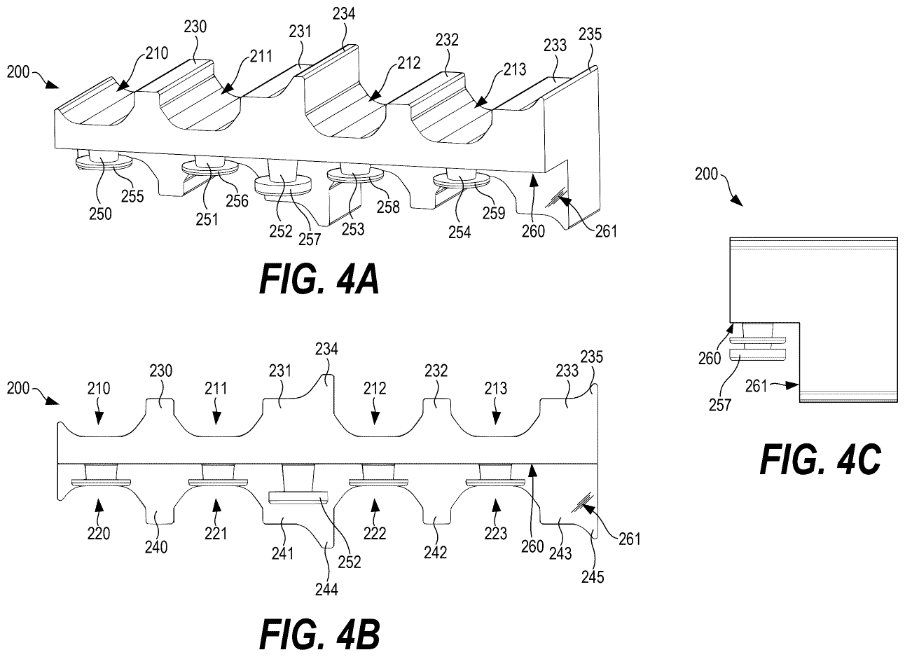

The board-edge cable organizer 200 can be formed from a plastic or polymer, such as a polycarbonate (PC), liquid crystal polymer (LCP), polyethylene (PE), polytetrafluoroethylene (PTFE), fluoropolymer, or other plastic or insulating material(s). The cable organizer 200 can be formed using any suitable additive or subtractive manufacturing techniques, including molding, injection molding, printing, and other techniques. In some cases, outer surfaces or certain surface areas of the cable organizer 200 can be plated with a plating metal or metals for conductivity, and the cable organizer 200 can be embodied as a plated plastic component. In other cases, the board-edge cable organizer 200 can be formed from a conductive material, such as one or more metals or metal alloys. The board-edge cable organizer 200 includes a number of cable channels, a board-side mounting surface, a board-edge abutment surface, mounting stakes, and fastening heads formed at the ends of the mounting stakes, among other features. These and other aspects of the board-edge cable organizer 200 are described below with reference to FIGS. 4A-4C.

Each of the inline cable organizers 270-273 can also be formed from a plastic or polymer, such as LCP, PE, PTFE, a fluoropolymer, or other plastic or insulating material(s). The cable organizers 270-273 can be formed using any suitable additive or subtractive manufacturing techniques, including molding, overmolding, injection molding, printing, and other techniques. In one approach, the cables 106 can be organized into rows or groups, such as a group of the cables 10A-10D, a group of the cables 20A-20D, a group of the cables 30A-30D, and a group of the cables 40A-40D (see also FIG. 5B). The cable organizer 273 can be overmolded around the group of the cables 10A-10D. The cable organizer 272 can be overmolded around the group of the cables 20A-20D. The cable organizer 271 can be overmolded around the group of the cables 30A-30D, and the cable organizer 270 can be overmolded around the group of the cables 40A-40D. In other case, the cable organizers 270-273 can be formed separately, and groups of the cables 106 can be inserted through apertures or openings through the cable organizers 270-273. In some cases, outer surfaces or certain surface areas of the cable organizers 270-273 can be plated with a plating metal or metals for conductivity, and the cable organizers 270-273 can be embodied as a plated plastic component. Each of the inline cable organizers 270-273 can be a separate part, piece, or component in one implementation. In other cases, the inline cable organizers 270-273 can be formed as a single (e.g., integral) part, piece, or component.

The cable bundle overmold 280 can also be formed from a plastic or polymer, such as PC, LCP, PE, PTFE, fluoropolymer, or other plastic or insulating material(s). The cable bundle overmold 280 can be formed using an additive, injection molding or overmolding technique in one case. For example, the cables 106 can be arranged and assembled with the board-edge cable organizer 200 and the inline cable organizers 270-273. Then, the assembly of the cables 106 and the cable organizers 200 and 270-273 can be inserted into a mold, and a polymer can be injected into the mold and between the cable organizers 200 and 270-273, to form the cable bundle overmold 280 between the cable organizers 200 and 270-273. These and other aspects of the cable bundle overmold 280 are described in further detail below.

FIG. 2C illustrates a detail perspective view of the PCB 130 and termination assembly shown in FIG. 2A. FIG. 2C illustrates how the cables 10A-10D and 20A-20D are terminated at and to the PCB 130. As an example, FIG. 2D also illustrates a perspective view of the distal end of the cable 10C in the termination assembly shown in FIG. 2C. Referring between FIGS. 2C and 2D, cable 10C includes two signal conductors 11A and 11B for data communication. The signal conductors 11A and 11B are surrounded by a core of dielectric insulating material 13 within the cable 10C, such as a solid or low-density polyolefin, PE, PTFE, fluoropolymer, or other plastic or insulating material. The cable 10C also includes a shield 14 (see FIG. 2D) around the dielectric insulating material 13, drain conductors 12A and 12B, and an outer jacket 15. Each of the cables 10A, 10B, 10D, 20A-20D, 30A-30D, and 40A-40D can be similar to the cable 10A.

The signal conductors 11A and 11B can be embodied as copper conductors, copper-clad steel conductors, or conductors formed from other metals. The conductors can include an outer-surface plating of silver or other metals in some cases. The conductors can range in gauge, such as between 24-34 AWG, although conductors of other gauges can be relied upon in twinax cables. Data signals can be differentially coupled to the signal conductors 11A and 11B, and the cable 10C can be used to communicate data using a range of modulation and signaling techniques. The conductors are electrically coupled to respective signal contact pads on the PCB 130.

The cable 10C includes a shield 14 (see FIG. 2D) around the dielectric insulating material 13. The shield 14 can be embodied as a relatively thin layer of conductive material, such as aluminum, copper, or other conductive shield layer, that is wrapped around and covers the outer surface of the dielectric insulating material 13. The drain conductors 12A and 12B can be embodied as aluminum, copper, or other metal conductors. The drain conductors 12A and 12B can range in gauge and can be a larger or smaller gauge than the signal conductors 11A and 11B. The drain conductors 12A and 12B contact and are electrically coupled with the shield 14. The drain conductors are also electrically coupled to respective ground pads on the PCB 130, as shown in FIG. 2C, when the termination assembly is assembled.

The jacket 15 of the cable 10C can be embodied as any suitable material capable of protecting and permitting sufficient flexibility for the cable 10C, such as polyvinylchloride (PVC), polyurethane, chlorinated PE, or other thermoplastic, thermoset, or related material. The jacket 15 of the cable 10C includes an opening 16. The opening 16 exposes a surface region 14A of the shield 14, as shown in FIG. 2D. The opening 16 is close to the distal end of the cable 10C. The shape, size, and position of the opening 16 is illustrated as a representative example in FIG. 2D. In other cases, the opening 16 can be larger, smaller, and located at different positions through the jacket 15. The opening 16 can also be formed as a notch or cutaway from an end edge of the jacket 15 of the cable 10C. The opening 16 can be formed by any suitable process or technique, including ablation using a laser or other heat source, cutting, scoring, or other approaches. Any or all of the cables 10A-10D, 20A-20D, 30A-30D, and 40A-40D can include an opening similar to the opening 16.

Although obscured from view in FIG. 2C, the PCB 130 includes rows of shield termination pockets. The shield termination pockets are described in further detail below with reference to FIGS. 3A and 3B. The shield termination pockets can be partial apertures or openings that extend into but not through the PCB 130. The PCB 130 includes shield termination pockets formed in the top surface 132 and shield termination pockets formed in the bottom surface 134. Surface regions of a ground plane of the PCB 130 are exposed within the shield termination pockets in some embodiments.

The distal ends of the cables 10A-10D, 20A-20D, 30A-30D, and 40A-40D are seated into the shield termination pockets where the cables are electrically coupled to the PCB 130. Conductive inlays can also be positioned between the ends of the cables 10A-10D, 20A-20D, 30A-30D, and 40A-40D and the shield termination pockets, as described in further detail below with reference to FIGS. 3A and 3B. For example, the end of cable 10C is seated into the shield termination pocket 60C (see FIG. 3A), and a conductive inlay 70C (see FIG. 3A) is positioned between the cable 10C and the termination pocket 60C. The conductive inlay 70C can provide an enhanced electrical coupling between the exposed surface region 14A of the shield 14 of the cable 10C, as shown in FIG. 2D, and the exposed ground plane of the PCB 130 within the termination pocket 60C. These and other aspects of the embodiments are described in further detail below.

FIG. 2C also illustrates how the cables 106 are organized and supported by the board-edge cable organizer 200, the inline cable organizers 270-273, and the cable bundle overmold 280. The cable organizers 200 and 270-273 and the cable bundle overmold 280 support the mechanical and electrical connections between the cables 106 and the PCB 130. The board-edge cable organizer 200 is secured along the back edge of the PCB 130. In the example illustrated, the board-edge cable organizer 200 is secured along and extends over an edge of the PCB 130 in a cantilevered arrangement.

FIG. 2C also illustrates a shield wall 50A, which is positioned between the cables 10B and 10C. The termination assembly can also include additional shield walls between other cables. The shield wall 50A can be embodied as a metal shield and is electrically coupled to ground contact pads on the top surface 132 of the PCB 130. The shield wall 50A can be mounted and positioned on the PCB 130 between the pockets 60B and 60C (see FIG. 3A) for the cables 10B and 10C. Other shield walls can be surface mounted between other cables and other pockets and on other surfaces of the PCB 130. The overall shape, size, and thickness of the shield wall 50A, among others, can vary as compared to the example depicted in FIG. 2C. In some cases, the shield wall 50A can be omitted from the assembly.

FIGS. 2E and 2F illustrate another perspective view of the PCB 130 and termination assembly shown in FIG. 2A. The cable bundle overmold 280 is omitted from view in FIG. 2F. FIGS. 2E and 2F also show how the cables 106 are organized and supported by the board-edge cable organizer 200, the inline cable organizers 270-273, and the cable bundle overmold 280. By comparing FIG. 2F with FIG. 2E, it is clear how the cable bundle overmold 280 is molded in part over and around the board-edge cable organizer 200 and the cables 106 extending along the channels in the board-edge cable organizer 200. The cables 106 extend through the inline cable organizers 270-273 and through the cable bundle overmold 280. Instead, rows of the cables 106 extend along cable channels formed in the board-edge cable organizer 200. The cable channels of the board-edge cable organizer 200 are described below with reference to FIGS. 4A-4C. Although the cables 106 extend across (e.g., rather than extending through) the board-edge cable organizer 200, the cables 106 are secured to the board-edge cable organizer 200 by the cable bundle overmold 280, which can be formed over (e.g., molded over) the cables 106 and around the board-edge cable organizer 200. However, the cable bundle overmold 280 can be omitted in some cases, and it may not be necessary in all implementations to secure the cables 106 to the board-edge cable organizer 200 using the cable bundle overmold 280.

FIG. 2G illustrates a perspective view of another example PCB 130A and termination assembly. The assembly shown in FIG. 2G is similar to that shown in FIGS. 2A-2F and described above, but the inline cable organizers 270-273 are arranged in a different way, the board-edge cable organizer 200A in FIG. 2G is different than the board-edge cable organizer 200 shown in FIGS. 2A-2F, and the cable bundle overmold 280A in FIG. 2G is different than the cable bundle overmold 280 shown in FIGS. 2A-2F. The PCB 130A shown in FIG. 2G is also an alternative example as compared to the PCB 130 shown in FIGS. 2A-2F.

The cable bundle overmold 280A is molded in part over and around the board-edge cable organizer 200A and the cables 106, which extend along the channels in the board-edge cable organizer 200A. The cables 106 extend through the inline cable organizers 270-273 and through the cable bundle overmold 280A. Rows of the cables 106 extend along cable channels formed in the board-edge cable organizer 200A, which is described in greater detail below with reference to FIGS. 3D and 3E. Although the cables 106 extend across (e.g., rather than extending through) the board-edge cable organizer 200A, the cables 106 are secured to the board-edge cable organizer 200A by the cable bundle overmold 280A, which can be formed over (e.g., molded over) the cables 106 and around the board-edge cable organizer 200A. However, the cable bundle overmold 280A can be omitted in some cases, and it may not be necessary in all implementations to secure the cables 106 to the board-edge cable organizer 200A using the cable bundle overmold 280A.

The inline cable organizers 270-273 are not positioned or abutted against the board-edge cable organizer 200A or the cable bundle overmold 280A in the example shown in FIG. 2G, as compared to the example shown in FIGS. 2A-2F. Instead, the inline cable organizers 270-273 are separated from the cable organizer 200A and the overmold 280A, along a length of the cables 106. The inline cable organizers 270-273 are also staggered in distance from the overmold 280A along a length of the cables 106 and are staggered in position with respect to each other. In the example shown, the inline cable organizers 271 and 273 are separated from the overmold 280A by a first distance “D1” along the cables 106. The inline cable organizers 270 and 272 are separated from the overmold 280A by a second distance “D2,” which is greater than the distance “D1”. Thus, the inline cable organizers 270-273 are stagged in position, along the length of the cables 106 and are separated from the overmold 280A. The inline cable organizers 270 and 272 are also separated from the overmold 280A by the distance “D1,” and the inline cable organizers 271 and 273 can be separated from the overmold 280A by the distance “D2” in other cases. Additionally, arrangement of the inline cable organizers shown in FIGS. 2A-2F can be combined with the arrangement of the inline cable organizers shown in FIG. 2G, such that a total of eight (8) rather than four (4) inline cable organizers can be relied upon.

Staggering the inline cable organizers 270-273 in position relative to each other permits the inline cable organizers 270-273 to be “nested” to some extent. In the arrangement shown in FIG. 2G, the distance from the bottom of the inline cable organizer 270 to the top of the inline cable organizer 273 can be reduced as compared to the arrangement shown in FIGS. 2A and 2B. Staggering the inline cable organizers 270-273, and the separation of the inline cable organizers 270-273 from the overmold 280A, can also help to promote flexibility among the rows of the cables 106, before the cables 106 are terminated to the PCB 130A, among other benefits. The distances “D1” and “D2” can vary among the implementations, depending on the overall size of the cable assembly and other factors. In a similar way, the inline cable organizers 271 and 273 are separated from the board-edge cable organizer 200A by a first distance along the cables 106. The inline cable organizers 270 and 272 are separated from the board-edge cable organizer 200A by a second distance, which is greater than the first distance. Thus, the inline cable organizers 270-273 are stagged in position along the length of the cables 106 and are separated from the board-edge cable organizer 200A.

The staggered arrangement of the inline cable organizers 270-273 can also vary as compared to that shown. In the example shown, the corners of the inline cable organizers 270-273 are aligned with and may contact each other, although the inline cable organizers 271 and 273 are staggered as compared to the inline cable organizers 270 and 272. In other implementations, the inline cable organizers 271 and 273 can be separated or spaced apart from the inline cable organizers 270 and 272, with a separation distance between them, such that none of the inline cable organizers 270-273 contact each other. In still other examples, the inline cable organizers 271 and 273 can be staggered with respect to the inline cable organizers 270 and 272, with partial surfaces of the inline cable organizers 271 and 273 overlapping with and contacting partial surfaces of the inline cable organizers 270 and 272.

FIG. 3A illustrates a top perspective view of the PCB 130 and the board-edge cable organizer 200 shown in FIG. 2A, and FIG. 3B illustrates a bottom perspective view of the PCB 130 and the board-edge cable organizer 200 shown in FIG. 2A. Shield termination pockets 60A-60D and 61A-61D (also “pockets”) of the PCB 130 are visible in FIG. 3A, and shield termination pockets 62A-62D and 63A-63D of the PCB 130 are visible in FIG. 3B. The pockets 60A-60D and 61A-61D are depressions, partial apertures, or partial openings that extend into the PCB 130 from the top surface 132. The pockets 62A-62D and 63A-63D are depressions, partial apertures, or partial openings that extend into the PCB 130 from the bottom surface 134.

A surface region of a ground plane of the PCB 130 is exposed within each of the pockets 60A-60D, 61A-61D, 62A-62D, and 63A-63D. For example, the surface region 80A of a ground plane of the PCB 130 is exposed within the pocket 60A, as shown in FIG. 3A. The sidewalls of each of the shield termination pockets 60A-60D, 61A-61D, 62A-62D, and 63A-63D can also be plated, conductive, and electrically coupled to the ground plane of the PCB 130. Thus, the sidewalls of the pocket 60A can be plated, conductive, and electrically coupled to the surface region 80A of the ground plane exposed within the pocket 60A.

The size and shape of the pockets 60A-60D, 61A-61D, 62A-62D, and 63A-63D is representative in FIGS. 3A and 3B. The pockets 60A-60D, 61A-61D, 62A-62D, and 63A-63D can vary in shape, size, and position as compared to that shown. The PCB 130 can also include more pockets or fewer pockets than those shown in FIGS. 3A and 3B. The row of pockets 60A-60D is offset from (e.g., not aligned with) the row of pockets 61A-61D, to facilitate routing the cables 10A-10D and the cables 20A-20D, and other arrangements and positions are within the scope of the embodiments.

An example conductive inlay 70C is also depicted in FIG. 3A. The conductive inlay 70C is positioned within the pocket 60C, but it should be appreciated that additional conductive inlays similar to the conductive inlay 70C can be positioned within any or all of the pockets 60A-60D, 61A-61D, 62A-62D, and 63A-63D in various embodiments. When the termination assembly is assembled, the conductive foam inlays can be positioned between an end of each of the cables 106 and the pockets 60A-60D, 61A-61D, 62A-62D, and 63A-63D. The conductive foam inlays can be embodied as flexible, elastic conductive foam, and can provide enhanced grounding and signal integrity for the termination assembly. The conductive foam inlays can be secured within one or more of the pockets 60A-60D, 61A-61D, 62A-62D, and 63A-63D using conductive pastes or adhesives in some cases.

The conductive foam inlays can be formed (i.e., by cutting, shaping, manufacturing, etc.) in a type of “U” or horseshoe shape in some examples, but conductive foam inlays can be formed in other shapes. Examples of other shapes include strips, rectangles, squares, and inlays with raised and curved sides. Two or more separate inlays can also be used in respective pockets 60A-60D, 61A-61D, 62A-62D, and 63A-63D in some cases. The inlays can also include curved and beveled surfaces or surface regions in some cases. The conductive foam inlays can also formed (i.e., dimensioned) to fit within the pockets 60A-60D and 61A-61D, possibly with a clearance between the sidewalls of the pockets 60A-60D, 61A-61D, 62A-62D, and 63A-63D and the conductive foam inlays. However, when the conductive foam inlays are compressed, they can expand laterally and contact the conductive sidewalls of the pockets 60A-60D, 61A-61D, 62A-62D, and 63A-63D.

The material from which the conductive foam inlays are formed can be elastic and compressible to some extent. As an example, the conductive foam inlays can be embodied as a polyurethane foam multi-laminate including conductive materials, such as copper, nickel, or other conductive metals or materials. In a particular example, the conductive foam inlays can be embodied as the P-SHIELD® brand PS-1323, PS-1768, or similar conductive foam, foam tape, or foam sheet manufactured by Polymer Science, Inc. of Monticello, Indiana, although other suitable types of conductive elastomeric or foam materials can be relied upon. The conductive foam inlays can range in thickness from between 0.1-1.0 mm, and example thicknesses include 0.1 mm, 0.2 mm, 0.3 mm, 0.4 mm, 0.5 mm, 0.6 mm, 0.7 mm, 0.8 mm, 0.9 mm, 1.0 mm, and other thicknesses can be relied upon. In another example, the conductive foam inlays can range in thickness from between 0.5-2.0 mm, and example thicknesses include 0.5 mm, 1.0 mm, 1.5 mm, and 2.0 mm, and other thicknesses can be relied upon.

When the cable 10C is terminated to the PCB 130, the conductive foam inlay 70C can be positioned in the pocket 60C, and the cable 10C can be positioned over the conductive foam inlay 70C, with the opening 16 (see FIG. 2D) in the jacket 15 aligned over the conductive foam inlay 70C. Thus, the conductive foam inlay 70C can make contact with the exposed surface region 14A of the shield 14 of the cable 10C, for improving grounding, interference rejection, and signal integrity. At the same time, the conductive foam inlay 70C can also be compressed and expand laterally to contact the exposed ground plane, conductive sidewalls, and other conductive grounding features within the pocket 60C.

FIG. 3C illustrates the board-edge cable organizer 200 separated from the PCB 130, so that the mounting apertures 138A-138E of the PCB 130 are visible. The mounting apertures 138A-138E can be positioned along a back edge 136 of the PCB 130. The mounting apertures 138A-138E extend through the PCB 130 from the top surface 132 to the bottom surface 134 of the PCB 130. Comparing FIGS. 3A and 3B with FIG. 3C, it is clear how the board-edge cable organizer 200 can be secured along and extends over the back edge 136 of the PCB 130 in a cantilevered arrangement.

The board-edge cable organizer 200 can include mounting stakes and fastening heads formed at the ends of the mounting stakes, as also described below with reference to FIGS. 4A-4C. The mounting stakes of the board-edge cable organizer 200 extend through the mounting apertures 138A-138E of the PCB 130, when the board-edge cable organizer 200 is secured with the PCB 130. The cable organizer 200 can also include fastening heads at the ends of the mounting stakes. The fastening heads can be positioned over the bottom surface 134 of the PCB 130 and secure the cable organizer 200 with the PCB 130, as shown in FIG. 3B.

FIG. 3D illustrates a top perspective view of the PCB 130A and board-edge cable organizer 200A shown in FIG. 2G, and FIG. 3E illustrates a bottom perspective view of the PCB 130A and board-edge cable organizer 200A shown in FIG. 2G. FIG. 3F illustrates a top perspective view of the PCB 130A and board-edge cable organizer 200A shown in FIG. 2G, separated from each other, according to aspects of the present disclosure. The top surface 132 of the PCB 130A is shown in FIGS. 3D and 3F, and the bottom surface 134 of the PCB 130A is shown in FIG. 3E. Shield termination pockets 60A-60D and 61A-61D of the PCB 130A, among others, are also visible in FIG. 3D, and shield termination pockets 62A-62D and 63A-63D of the PCB 130A are also visible in FIG. 3E. FIGS. 3D-3F also illustrate the board-edge cable organizer 200A. The board-edge cable organizer 200A is similar to the board-edge cable organizer 200 shown in FIGS. 3A-3C, but the board-edge cable organizer 200A is relatively longer than the board-edge cable organizer 200. The board-edge cable organizer 200A can be secured along and extends over the back edge of the PCB 130A in a cantilevered arrangement.

Referring among FIGS. 3D-3F, the board-edge cable organizer 200A includes upper cable channels 210A-213A, lower cable channels 220A-223A, cable separation pillars, such as the cable separation pillar 230A, among others, mounting stakes 250A-250D, a board-edge abutment surface 261A, and other features described below. FIGS. 3D-F illustrate a representative example of the board-edge cable organizer 200A. The board-edge cable organizer 200A can vary in shape, size, and other aspects in other embodiments. The board-edge cable organizer 200A can include additional or fewer cable channels, cable separation pillars, cable bumpers, mounting stakes, and other features depending on the application and design needs.

The cable channels 210A-213A and 220A-223A of the cable organizer 200A provide channels or regions in which rows of the cables 106 can be seated, secured, and organized. The cable channels 210A-213A are positioned on a first or top side of the cable organizer 200A, and the cable channels 220A-223A are positioned on a second or bottom side of the cable organizer 200A. The cable channels 210A-213A and 220A-223A can be arranged at different positions, either closer together or spread further apart from each other, in other cases.

The cables 106 extend in and along the cable channels 210A-213A and 220A-223A of the board-edge cable organizer 200A. For example, the cables 20A-20D (see FIG. 2C) can extend in and along the cable channels 210A-213A on the first or top side of the cable organizer 200A, and the cables 10A-10D (see FIG. 2C) can extend over the cables 20A-20D, along the cable separation pillar 230A, among others, of the cable organizer 200A. The cables 30A-30D (see FIG. 2B) also extend in and along the cable channels 220A-223A on the second or bottom side of the cable organizer 200A, and the cables 40A-40D (see FIG. 2C) can extend over the cables 30A-30D. The overmold 280A (see FIG. 2G) can be formed over the cables 106 and the board-edge cable organizer 200A, after the cables 106 are positioned and seated within the cable channels 210A-213A and 220A-223A of the board-edge cable organizer 200A.

As shown in FIG. 3F, the mounting stakes 250A-250D of the of the cable organizer 200A help to secure the cable organizer 200A to the PCB 130A. The mounting stakes 250A-250D of the cable organizer 200A extend through the mounting apertures 139A-139D of the PCB 130A, respectively, when the board-edge cable organizer 200A is formed and secured with the PCB 130A. The cable organizer 200A can be secured to the PCB 130A in a variety of ways. In one example, the cable organizer 200A can be formed along the back edge 136A of the PCB 130A as part of a molding process. For example, the PCB 130A can be inserted into a mold. The cable organizer 200A can then be formed (e.g., injection molded) along the back edge 136A of the PCB 130A as part of a molding process, with the mounting stakes 250A-250D being formed along with the rest of the cable organizer 200A. The cable organizer 200A can also be secured to the PCB 130A using other fastening means, such as using clips, hooks, or other mechanical interferences, or friction fits. In other examples, pins, screws, interlocks, or other fastening means can be relied upon to secure the cable organizer 200A to the PCB 130A.

FIG. 4A illustrates a perspective view, FIG. 4B illustrates a front view, and FIG. 4C illustrates a side view of the board-edge cable organizer 200. The board-edge cable organizer 200 includes cable channels 210-213 and 220-223, cable separation pillars 230-233 and 240-243, cable bumpers 234, 235, 244, and 245, mounting stakes 250-254, fastening heads 255-259 at the ends of the mounting stakes 250-254, a board-side mounting surface 260, and a board-edge abutment surface 261. FIGS. 4A-4C illustrate a representative example of a board-edge cable organizer according to the embodiments. The board-edge cable organizer 200 can vary in shape, size, and other aspects in other embodiments. The board-edge cable organizer 200 can include additional or fewer cable channels, cable separation pillars, cable bumpers, mounting stakes, and other features depending on the application and design needs.

The cable channels 210-213 and 220-223 of the cable organizer 200 provide channels or regions in which rows of the cables 106 can be seated, secured, and organized. The cable channels 210-213 are positioned on a first or top side of the cable organizer 200, and the cable channels 220-223 are positioned on a second or bottom side of the cable organizer 200. The cable channels 210 and 211 are separated apart from each other by a same distance that the cable channels 220 and 221, the cable channels 212 and 213, and the cable channels 222 and 223 are separated apart from each other. However, the separation space or distance between the cable channels 211 and 212 is larger than that between the cable channels 210 and 211. The separation space or distance between the cable channels 221 and 222 is also larger than that between the cable channels 220 and 221. The cable channels 210-213 and 220-223 can be arranged at different positions, either closer together or spread further apart from each other, in other cases.

As described in further detail below with reference to FIGS. 5A and 5B, the cables 20A-20D extend in and along the cable channels 210-213 of the board-edge cable organizer 200. Additionally, the cables 30A-30D extend in and along the cable channels 220-223 of the board-edge cable organizer 200. Thus, the cables 20A-20D extend in and along the cable channels 210-213 on the first or top side of the cable organizer 200, and the cables 30A-30D extend in and along the cable channels 220-223 on the second or bottom side of the cable organizer 200. The cable bumpers 234, 235, 244, and 245 extend up from the cable separation pillars 231, 233, 241, and 243, respectively. The cable bumpers 234, 235, 244, and 245 provide mechanical interferences to help position the cables 10A-10D over the cables 20A-20D and to help position the cables 40A-40D over the cables 30A-30D.

The cable separation pillars 230-233 and 240-243 of the cable organizer 200 are positioned between and separate the cable channels 210-213 and 220-223. The cable organizer 200 also includes cable bumpers 234, 235, 244, and 245. The cable bumpers 234, 235, 244, and 245 extend up from the cable separation pillars 231, 233, 241, and 243, respectively. The cable bumpers 234, 235, 244, and 245 provide mechanical interferences to help position the cables 10A-10D and 40A-40D.

The mounting stakes 250-254 of the of the cable organizer 200 are provided to secure the cable organizer 200 to the PCB 130. The mounting stakes 250-254 of the cable organizer 200 extend through the mounting apertures 138A-138E of the PCB 130, which are shown in FIG. 3C, when the board-edge cable organizer 200 is secured with the PCB 130. Additionally, the fastening heads 255-259, which are formed at the ends of the mounting stakes 250-254, are positioned over the bottom surface 134 of the PCB 130 and secure the cable organizer 200 with the PCB 130, as shown in FIG. 3B.

The board-side mounting surface 260 of the cable organizer 200 faces the top surface 132 of the PCB 130 when the cable organizer 200 is assembled with the PCB 130, as shown in FIGS. 3A-3C. Additionally, the board-edge abutment surface 261 of the of the cable organizer 200 faces the back edge 136 of the PCB 130.

The cable organizer 200 can be secured to the PCB 130 in a variety of ways. In one example, the cable organizer 200 can be formed separately from the PCB 130. The mounting stakes 250-254 of the cable organizer 200 can be initially formed without the fastening heads 255-259. The cable organizer 200 can then be positioned on the PCB 130 with the mounting stakes 250-254 extending through the mounting apertures 138A-138E of the PCB 130. In that arrangement, the board-side mounting surface 260 of the cable organizer 200 will face the top surface 132 of the PCB 130, and the board-edge abutment surface 261 of the of the cable organizer 200 will face the back edge 136 of the PCB 130. Then, a heat staking process can be performed to partially melt, reflow, and reform the distal ends of the mounting stakes 250-254 into the fastening heads 255-259.

In another example, the cable organizer 200 can be immediately formed along the back edge 136 of the PCB 130 in a single, primary molding process. For example, the PCB 130 can be inserted into a mold. The cable organizer 200 can then be formed (e.g., injection molded) along the back edge 136 of the PCB 130 in a primary molding process, with the mounting stakes 250-254 and fastening heads 255-259 being formed in a single molding step along with the rest of the cable organizer 200. In any case, the fastening heads 255-259 provide a mechanical interference against the bottom surface 134 of the PCB 130, securing the cable organizer 200 with the PCB 130.

The cable organizer 200 can also be secured to the PCB 130 using other fastening means, besides the mounting stakes 250-254 and fastening heads 255-259. Clips, hooks, or other mechanical interference, friction fit, or related fastening means can be formed at the ends of the mounting stakes 250-254 for securing the cable organizer 200 can also be secured to the PCB 130. In other examples, pins, screws, interlocks, or other fastening means can be relied upon to secure the cable organizer 200 to the PCB 130.

FIG. 5A illustrates the sectional view of the PCB 130 and termination assembly designated A-A in FIG. 2F, and FIG. 5B illustrates the sectional view of the PCB 130 and termination assembly designated B-B in FIG. 2F. FIG. 5A illustrates a cross-section of the PCB 130 along with the cable organizer 200. The mounting stakes of the cable organizer 200 are shown extending through the PCB 130 in FIG. 5A, with the mounting stake 252 being referenced. FIG. 5B does not illustrate the PCB 130, because the cable organizer 200 is hanging off the end of and does not intersect with the PCB 130 in FIG. 5B.

FIGS. 5A and 5B show how the board-edge cable organizer 200 can be relied upon to secure, organize, and space apart the rows of cables 10A-10D, 20A-20D, 30A-30D, and 40A-40D. The cables 20A-20D extend in and along the cable channels 210-213 (see FIGS. 4A and 4B) of the board-edge cable organizer 200. Additionally, the cables 30A-30D extend in and along the cable channels 220-223 of the board-edge cable organizer 200. Thus, the cables 20A-20D extend in and along the cable channels 210-213 on the first or top side of the cable organizer 200, and the cables 30A-30D extend in and along the cable channels 220-223 on the second or bottom side of the cable organizer 200. The cables 10A-10D can also be positioned over the cables 20A-20D on the first or top side of the cable organizer 200, and cables 40A-40D can also be positioned over the cables 30A-30D on the second or bottom side of the cable organizer 200.

FIGS. 5A and 5B also show how the inline cable organizers 270-273 can be relied upon to secure, organize, and space apart the rows of cables 10A-10D, 20A-20D, 30A-30D, and 40A-40D. The cables 10A-10D extend through apertures in the cable organizer 273. The cables 20A-20D extend through apertures in the cable organizer 272. Further, the cables 30A-30D extend through apertures in the cable organizer 271, and the cables 40A-40D extend through apertures in the cable organizer 270. The cables 10A-10D, 20A-20D, 30A-30D, and 40A-40D extend through the cable organizers 270-273 before extending along the channels in the cable organizer 200. The cables 10A-10D, 20A-20D, 30A-30D, and 40A-40D extend a length “L” between the inline cable organizers 270-273 and the board-edge cable organizer 200. The length “L” can vary among the embodiments.

In one example, the cable bundle overmold 280 can be injection molded between the board-edge cable organizer 200 and the inline cable organizers 270-273 after the cables 10A-10D, 20A-20D, 30A-30D, and 40A-40D and the cable organizers 200 and 270-273 have been assembled with the PCB 130 as shown in FIGS. 5A and 5B (and as shown in FIG. 2F). The assembly of the cables and cable organizers can be inserted into a mold, and a plastic or polymer can be injected into the mold and between the cable organizers 200 and 270-273 to form the cable bundle overmold 280. The cable bundle overmold 280 can be formed to occupy free space around the cables between the cable organizers 200 and 270-273 during the molding process. The cable organizers 200 and 270-273 can act to control and stop the flow of material for the cable bundle overmold 280.

FIGS. 5A and 5B also illustrate how the cables 106 are organized and supported by the board-edge cable organizer 200. The board-edge cable organizer 200 supports the mechanical and electrical connections between the cables 106 and the PCB 130. The board-edge cable organizer 200 is secured to the PCB 130 at the back edge of the PCB 130 and provides stress and strain relief between the cables 106 and the PCB 130. As noted above, the cables 106 can include conductors of relatively large diameters (e.g., conductors of lower AWG) in some cases to facilitate higher data throughputs. Larger conductors can transfer and exert larger forces, including where the conductors of the cables 106 are terminated to the PCB 130. Even with the use of larger conductors in the cables 106, the board-edge cable organizer 200, inline cable organizers 270-273, and cable bundle overmold 280 can help to maintain mechanical robustness in termination assemblies. It should be appreciated that the board-edge cable organizer 200, inline cable organizers 270-273, and cable bundle overmold 280 are described and illustrated as examples herein. The cable organizers 200 and 270-273 can vary in shape and size in some cases, for example, depending on the number of cables used, etc., and the concepts can be extended to use with other termination assemblies. Also, in some cases, one or more of the cable organizers 200 and 270-273 and/or the cable bundle overmold 280 can be omitted.

Terms such as “top,” “bottom,” “side,” “front,” “back,” “right,” and “left” are not intended to provide an absolute frame of reference. Rather, the terms are relative and are intended to identify certain features in relation to each other, as the orientation of structures described herein can vary. The terms “comprising,” “including,” “having,” and the like are synonymous, are used in an open-ended fashion, and do not exclude additional elements, features, acts, operations, and so forth. Also, the term “or” is used in its inclusive sense, and not in its exclusive sense, so that when used, for example, to connect a list of elements, the term “or” means one, some, or all of the elements in the list.

Combinatorial language, such as “at least one of X, Y, and Z” or “at least one of X, Y, or Z,” unless indicated otherwise, is used in general to identify one, a combination of any two, or all three (or more if a larger group is identified) thereof, such as X and only X, Y and only Y, and Z and only Z, the combinations of X and Y, X and Z, and Y and Z, and all of X, Y, and Z. Such combinatorial language is not generally intended to, and unless specified does not, identify or require at least one of X, at least one of Y, and at least one of Z to be included.

The terms “about” and “substantially,” unless otherwise defined herein to be associated with a particular range, percentage, or related metric of deviation, account for at least some manufacturing tolerances between a theoretical design and manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

The above-described embodiments of the present disclosure are merely examples of implementations to provide a clear understanding of the principles of the present disclosure. Many variations and modifications can be made to the above-described embodiments without departing substantially from the spirit and principles of the disclosure. In addition, components and features described with respect to one embodiment can be included in another embodiment. All such modifications and variations are intended to be included herein within the scope of this disclosure.

At least the following is claimed:

1. A termination assembly, comprising:
a printed circuit board (PCB);
a board-edge cable organizer secured along an edge of the PCB, the board-edge cable organizer comprising a cable channel; and
a cable extending in and along the cable channel of the board-edge cable organizer and being electrically coupled with the PCB.

2. The termination assembly according to claim 1, further comprising: an inline cable organizer, wherein:
from one end, the cable extends through the inline cable organizer, in and along the cable channel of the board-edge cable organizer, and to the PCB.

3. The termination assembly according to claim 2, wherein:
the cable comprises a plurality of cables;
the termination assembly further comprises a plurality of inline cable organizers, with a first cable among the plurality of cables extending through a first inline cable organizer among the plurality of cable organizers and a second cable among the plurality of cables extending through a second inline cable organizer among the plurality of cable organizers;
the first inline cable organizer is separated by a first distance from the board-edge cable organizer; and
the second inline cable organizer is separated by a second distance from the board-edge cable organizer different than the first distance.

4. The termination assembly according to claim 1, wherein the board-edge cable organizer is secured along and extends over the edge of the PCB in a cantilevered arrangement.

5. The termination assembly according to claim 1, wherein the board-edge cable organizer further comprises:
a board-side mounting surface;
a plurality of mounting stakes; and
a plurality of cable channels.

6. The termination assembly according to claim 5, wherein:
the board-edge cable organizer further comprises a board-edge abutment surface;
the board-side mounting surface faces a top surface of the PCB; and
the board-edge abutment surface faces an edge of the PCB.

7. The termination assembly according to claim 5, wherein:
the board-side mounting surface faces a top surface of the PCB; and
the plurality of mounting stakes extend through mounting apertures in the PCB from the top surface to a bottom surface of the PCB.

8. The termination assembly according to claim 7, wherein each of the plurality of mounting stakes comprises a fastening head over the bottom surface of the PCB.

9. The termination assembly according to claim 1, wherein the board-edge cable organizer further comprises:
a plurality of cable channels; and
a cable separation pillar between two of the plurality of cable channels.

10. The termination assembly according to claim 9, wherein the cable separation pillar comprises a cable bumper extending beyond an end surface of the cable separation pillar.

11. The termination assembly according to claim 1, wherein the board-edge cable organizer further comprises:
a first plurality of cable channels on a first side of the board-edge cable organizer; and
a second plurality of cable channels on a second side of the board-edge cable organizer.

12. The termination assembly according to claim 1, further comprising:
a cable bundle comprising the cable among a plurality of cables, wherein:
the board-edge cable organizer further comprises:
a first plurality of cable channels on a first side of the board-edge cable organizer; and
a second plurality of cable channels on a second side of the board-edge cable organizer; and
a first cable among the plurality of cables extends in and along a first cable channel among the first plurality of cable channels on the first side of the board-edge cable organizer; and
a second cable among the plurality of cables extends in and along a second cable channel among the second plurality of cable channels on the second side of the board-edge cable organizer.

13. A termination assembly, comprising:
a printed circuit board (PCB);
a board-edge cable organizer secured along an edge of the PCB; and
a cable extending along the board-edge cable organizer and being electrically coupled with the PCB.

14. The termination assembly according to claim 13, wherein:
the cable comprises a plurality of cables;
the termination assembly further comprises a plurality of inline cable organizers, with a first cable among the plurality of cables extending through a first inline cable organizer among the plurality of cable organizers and a second cable among the plurality of cables extending through a second inline cable organizer among the plurality of cable organizers;
the first inline cable organizer is separated by a first distance from the board-edge cable organizer; and
the second inline cable organizer is separated by a second distance from the board-edge cable organizer different than the first distance.

15. The termination assembly according to claim 14, further comprising:
a cable bundle overmold, wherein:
from one end, the cable extends through the inline cable organizer, through the cable bundle overmold, along the board-edge cable organizer, and to the PCB.

16. The termination assembly according to claim 13, wherein the board-edge cable organizer is secured along and extends over the edge of the PCB in a cantilevered arrangement.

17. The termination assembly according to claim 13, wherein the board-edge cable organizer further comprises:
a board-side mounting surface; and
a plurality of mounting stakes.

18. The termination assembly according to claim 17, wherein:
the board-side mounting surface faces a top surface of the PCB; and
the plurality of mounting stakes extend through mounting apertures in the PCB from the top surface to a bottom surface of the PCB.

19. The termination assembly according to claim 13, wherein the board-edge cable organizer further comprises:
a plurality of cable channels; and
a cable separation pillar between each of the plurality of cable channels.

20. The termination assembly according to claim 13, further comprising:
a cable bundle comprising the cable among a plurality of cables, wherein:
the board-edge cable organizer further comprises:
a first plurality of cable channels on a first side of the board-edge cable organizer; and
a second plurality of cable channels on a second side of the board-edge cable organizer; and
a first cable among the plurality of cables extends in and along a first cable channel among the first plurality of cable channels on the first side of the board-edge cable organizer; and
a second cable among the plurality of cables extends in and along a second cable channel among the second plurality of cable channels on the second side of the board-edge cable organizer.
